(19) United States
(12) Patent Application Publication
(10) Pub. No.: US 2021/0334440 A1
(43) Pub. Date: Oct. 28, 2021

(54) MODEL OPTIMIZATION DEVICE, MODEL OPTIMIZATION METHOD, AND PROGRAM

(71) Applicant: MITSUBISHI HEAVY INDUSTRIES, LTD., Tokyo (JP)

(72) Inventors: Yusuke YAMASHINA, Tokyo (JP); Kenji TAKAO, Tokyo (JP); Eriko SHINKAWA, Tokyo (JP)

(21) Appl. No.: 17/229,175

(22) Filed: Apr. 13, 2021

(30) Foreign Application Priority Data
Apr. 28, 2020 (JP) 2020-079457

(51) Int. Cl. G06F 30/27; G06N 3/08; G06N 3/04; G06K 9/62

(52) U.S. Cl. CPC G06F 30/27; G06N 3/08; G06K 9/6218; G06K 9/6262; G06N 3/0454

(57) ABSTRACT

A model optimization device is configured to optimize a prediction model configured to generate predicted values of a target variable for an explanatory variable. The model optimization device includes a generating unit configured to generate expanded MR data by transforming training data, and an optimization unit configured to cause the prediction model to learn and optimize the prediction model based on a first predicted value generated by the prediction model based on the training data, and a second predicted value generated by the prediction model based on the MR data.

### CROSS-REFERENCE TO RELATED APPLICATIONS

This application claims the benefit of priority to Japanese Patent Application Number 2020-079457 filed on Apr. 28, 2020. The entire contents of the above-identified application are hereby incorporated by reference.

### TECHNICAL FIELD

The present disclosure relates to a model optimization device, a model optimization method, and a program for optimizing a prediction model.

### RELATED ART

Prediction models configured to perform machine learning using training data and generate predicted values of target variables for explanatory variables have been proposed. For example, JP 2020-27556 A discloses a device that performs machine learning. The device is configured to learn using training data including status data and control condition data and output recommended control condition data (a target variable) indicating a recommended control condition for each target device in response to an input of the status data (an explanatory variable).

Incidentally, in recent years, metamorphic testing (MT) has been proposed as a method for evaluating systems. In MT, the system is evaluated using a relationship called metamorphic relations (MR). MR is a relationship that can be used to predict a change in output data when a predetermined change is applied to input data. For example, a relationship indicating that the calculation result of the value of sin(π) and the calculation result of the value of sin(π+2π) are the same is also MR.

### SUMMARY

In prediction models using machine learning in the related art, robustness may not be ensured due to the unbalance of training data or evaluation data. For example, in a case where a prediction model is applied to a plant having varying characteristics depending on the outdoor temperature, if the prediction model is taught only with training data acquired in summer, prediction accuracy in winter may decrease. For example, component degradation of the plant may change performance, which may decrease prediction accuracy. In addition, due to individual differences in components and differences in fuel properties, operating conditions may deviate from the operating conditions at the time of learning, and the prediction accuracy may decrease.

In this way, in a case where robustness cannot be ensured, the prediction model may be refrained from being applied to an actual machine, and the prediction model may be used with doubts about prediction results. For this reason, a technique has also been proposed in which new data is generated using MR to complement the unbalance of the training data and the evaluation data, and the MT is executed using the data. For example, in image recognition, a method of generating MR data obtained by rotating training data and executing MT has been proposed. However, such newly generated MR data may also include data that cannot actually occur. In addition, MT is used exclusively for system evaluation (for example, performance evaluation of a prediction model). Thus, MT itself is not a technique for improving the robustness of a prediction model.

In view of the above-described circumstances, an object of the present disclosure is to provide a model optimization device or the like capable of improving the robustness of a prediction model.

According to the present disclosure, there is provided a model optimization device that optimizes a prediction model configured to generate predicted values of a target variable for an explanatory variable. The model optimization device includes a generating unit configured to generate expanded MR data by transforming training data; and an optimization unit configured to cause the prediction model to learn and optimize the prediction model based on a first predicted value generated by the prediction model based on the training data, and a second predicted value generated by the prediction model based on the MR data.

According to the present disclosure, there is provided a model optimization method for optimizing a prediction model configured to generate predicted values of a target variable for an explanatory variable. The model optimization method includes generating expanded MR data by transforming training data; and causing the prediction model to learn and optimizing the prediction model based on a first predicted value generated by the prediction model based on the training data, and a second predicted value generated by the prediction model based on the MR data.

According to the present disclosure, there is provided a program for causing a computer to optimize a prediction model configured to generate predicted values of a target variable for an explanatory variable. The program causes the computer to execute generating expanded MR data by transforming training data; and causing the prediction model to learn and optimizing the prediction model based on a first predicted value generated by the prediction model based on the training data, and a second predicted value generated by the prediction model based on the MR data.

According to the present disclosure, it is possible to provide a model optimization device or the like capable of improving the robustness of a prediction model.

### BRIEF DESCRIPTION OF DRAWINGS

The disclosure will be described with reference to the accompanying drawings, wherein like numbers reference like elements.

FIG. 1 is a block diagram schematically illustrating a configuration of a prediction system including a model optimization device according to an embodiment.

FIG. 2 is a block diagram schematically illustrating a configuration of a prediction system including a model optimization device according to the embodiment.

FIG. 3 is a block diagram schematically illustrating a configuration of the model optimization device according to the embodiment.

FIG. 4 is a diagram illustrating an example of time series data indicating temporal changes in an explanatory variable and a target variable.

FIG. 5 is a conceptual diagram illustrating a clustering process executed by the model optimization device according to the embodiment.

FIG. 6A is a conceptual diagram illustrating an example (increase or decrease in consideration of slope) of MR data of an explanatory variable generated by the model optimization device according to the embodiment.

FIG. 6B is a conceptual diagram illustrating an example of a target variable (a second predicted value) acquired by the model optimization device according to the embodiment based on the MR data illustrated in FIG. 6A.

FIG. 7 is a conceptual diagram illustrating an example (offset) of MR data generated by the model optimization device according to the embodiment.

FIG. 8 is a conceptual diagram illustrating an example (simulation of time constant change) of MR data generated by the model optimization device according to the embodiment.

FIG. 9 is a conceptual diagram illustrating an example (simulation of tendency change due to time inversion) of MR data generated by the model optimization device according to the embodiment.

FIG. 10A is a conceptual diagram illustrating an example of verification data used by the model optimization device according to the embodiment.

FIG. 10B is a conceptual diagram illustrating an example of MR data generated from the verification data illustrated in FIG. 10A.

FIG. 10C is a conceptual diagram illustrating an example of MR data generated from the verification data illustrated in FIG. 10A.

FIG. 11A is a conceptual diagram illustrating an example of a process of generating MR data by the model optimization device according to the embodiment.

FIG. 11B is a conceptual diagram illustrating an example of a process of generating MR data by the model optimization device according to the embodiment.

FIG. 11C is a conceptual diagram illustrating an example of a process of generating MR data by the model optimization device according to the embodiment.

FIG. 12 is a schematic diagram illustrating a specific example of evaluation results using the model optimization device according to the embodiment.

FIG. 13 is a flowchart illustrating an optimization process by the model optimization device according to the embodiment.

FIG. 14 is a flowchart illustrating an optimization process by the model optimization device according to the embodiment.

FIG. 15 is a flowchart illustrating an optimization process by the model optimization device according to the embodiment.

### DESCRIPTION OF EMBODIMENTS

Embodiments will be described hereinafter with reference to the appended drawings. It is intended, however, that unless particularly specified, dimensions, materials, shapes, relative positions and the like of components described in the embodiments shall be interpreted as illustrative only and not intended to limit the scope of the disclosure.

For instance, an expression of relative or absolute arrangement such as “in a direction”, “along a direction”, “parallel”, “orthogonal”, “centered”, “concentric” and “coaxial” shall not be construed as indicating only the arrangement in a strict literal sense, but also includes a state where the arrangement is relatively displaced by a tolerance, or by an angle or a distance within a range in which it is possible to achieve the same function.

For instance, an expression of an equal state such as “same”, “equal”, “uniform” and the like shall not be construed as indicating only the state in which the feature is strictly equal, but also includes a state in which there is a tolerance or a difference within a range where it is possible to achieve the same function.

Further, for instance, an expression of a shape such as a rectangular shape, a cylindrical shape or the like shall not be construed as only the geometrically strict shape, but also includes a shape with unevenness, chamfered corners or the like within the range in which the same effect can be achieved.

On the other hand, an expression such as “comprise”, “include”, “have”, “contain” and “constitute” are not intended to be exclusive of other constituent elements.

### Overall Configuration of Prediction System

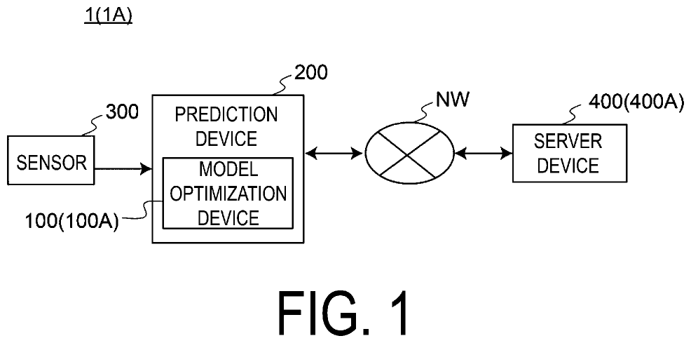

Hereinafter, a configuration of a prediction system 1 including a model optimization device 100 according to an embodiment will be described. FIG. 1 is a block diagram schematically illustrating a configuration of a prediction system 1 (1A) including a model optimization device 100 (100A) according to an embodiment.

As illustrated in FIG. 1, the prediction system 1 (1A) includes one or more sensors 300 provided in a facility such as a plant, a prediction device 200 configured to acquire measured values from the one or more sensors 300 and predict target variables in a case where the measured values are used as explanatory variables, and a server device 400 (400A) configured to communicate with the prediction device 200 via a network NW. The prediction device 200 includes the model optimization device 100 (100A) for optimizing the prediction model, and makes a prediction based on a stored prediction model.

Note that the network NW is, for example, a wide area network (WAN) or a local area network (LAN). Gateway devices such as modems and routers are not illustrated.

In the prediction system 1 (1A), the prediction device 200 is disposed at a place (local location) provided with a facility such as a plant, and the server device 400 (400A) is disposed at a monitoring site (remote location). Prediction results of the prediction device 200 are transmitted to the server device 400 (400A). An operator may check the prediction results of the prediction device 200 via the server device 400 (400A), and transmit various instruction signals to the prediction device 200 via the server device 400 (400A) and the network NW. With the prediction system 1 (1A), prediction and optimization can be performed at a local location.

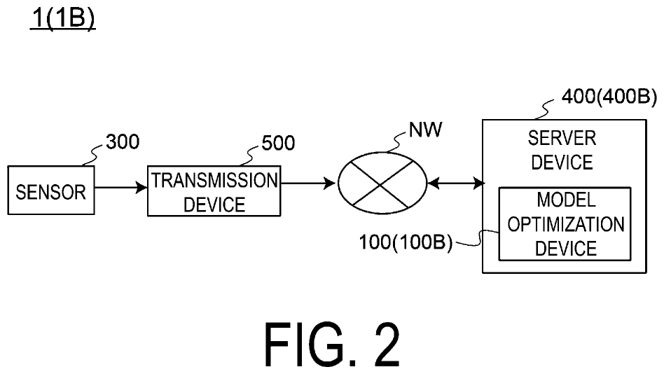

FIG. 2 is a block diagram schematically illustrating a configuration of a prediction system 1 (1B) including a model optimization device 100 (100B) according to the embodiment. As illustrated in FIG. 2, the prediction system 1 (1B) includes one or more sensors 300 provided in a facility such as a plant, a transmission device 500 configured to acquire measured values from the one or more sensors 300 and transmit the measured values to a server device 400 (400B) via a network NW, and the server device 400 (400B) configured to communicate with the transmission device 500 via the network NW. The server device 400 (400B) includes the model optimization device 100 (100B) for optimizing the prediction model, and makes a prediction based on a stored prediction model.

In the prediction system 1 (1B), the transmission device 500 is disposed at a place (local location) provided with a facility such as a plant, and the server device 400 (400B) is disposed at a monitoring site (remote location). The server device 400 (400B) is configured to predict target variables in a case where the measured values received from the transmission device 500 are used as explanatory variables. An operator may check the prediction results output from the server device 400 (400B). According to the prediction system 1 (1B), prediction and optimization can be performed at a remote location.

Note that the configuration of the prediction system 1 is not limited to an edge type as illustrated in FIG. 1 or a cloud type as illustrated in FIG. 2. For example, the prediction system 1 may have a local configuration that does not use the network NW. In this case, prediction and optimization can be performed at a local location, and an operator can check prediction results at the local location. Furthermore, the prediction system 1 can be configured to make a prediction at a local location and perform processing necessary for optimization at a remote location. For example, such a configuration can be realized by disposing the prediction device 200 having a prediction model stored thereon at a local location, disposing the model optimization device 100 at a remote location, and communicatively connecting the two.

The model optimization device 100 may be constituted by a plurality of devices instead of one device. That is, the model optimization device 100 may be implemented by cooperation of a plurality of devices by dispersing functions in the plurality of devices. The model optimization device 100 may be a device independent of the prediction device 200 and the server device 400.

The prediction model may have a configuration in which a relationship between explanatory variables and target variables in the same time zone is modeled. For example, as in the embodiment illustrated in FIGS. 1 and 2, the explanatory variables input to the prediction model are measured values from the one or more sensors 300, and the target variables output from the prediction model may be a control command in accordance with the measured values. In this case, it is suitable for performing optimal control based on the measured value.

However, the prediction model is not limited to such a configuration. The prediction model may have a configuration in which a relationship between explanatory variables and target variables in different time zones is modeled. For example, the prediction model may have a configuration in which a relationship between an explanatory variable in a certain time zone and a target variable in a time zone in the future rather than the time zone of the explanatory variable is modeled. In this case, it is suitable for predicting future target variables, creating an operation plan for future facility, and the like. For example, it is possible to cause a prediction model to predict future weather and power generating capacity based on a measured value of the current outdoor temperature. As described above, the explanatory variables and the target variables may be data in the same time zone, or data in different time zones.

### Configuration of Model Optimization Device

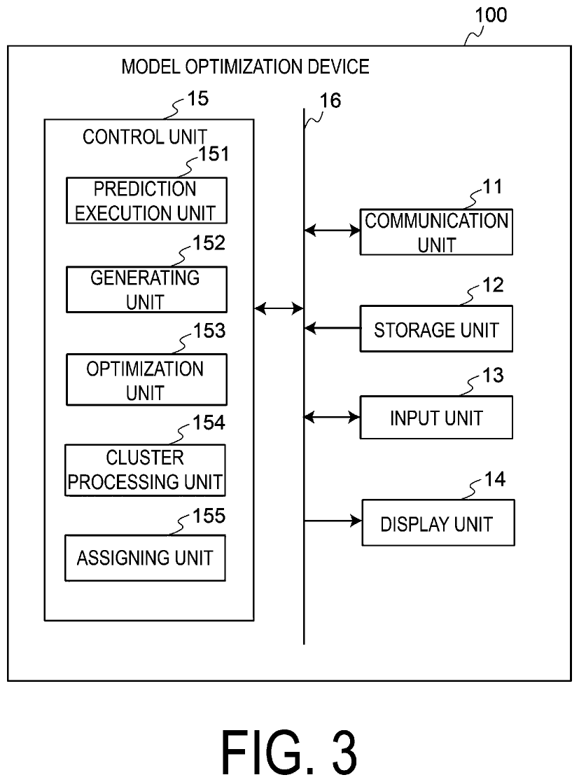

Hereinafter, a configuration of the model optimization device 100 according to the embodiment will be described. FIG. 3 is a block diagram schematically illustrating a configuration of the model optimization device 100 according to the embodiment. Note that, in the following description, a case where the model optimization device 100 is implemented by one device will be described as one example, but as described above, the model optimization device 100 is not limited to such a configuration.

As illustrated in FIG. 3, the model optimization device 100 includes a communication unit 11 configured to communicate with other devices, a storage unit 12 configured to store various types of data, an input unit 13 configured to receive user input, a display unit 14 for presenting information to a user, and a control unit 15 configured to control the overall device. These components are connected to each other by a bus line 16. Note that the communication unit 11, the input unit 13, and the display unit 14 can be omitted as appropriate depending on the application conditions of the model optimization device 100.

The communication unit 11 is a communication interface including a network interface card controller (NIC) for performing wired communication or wireless communication. The communication unit 11 communicates with other devices via the network NW such as a WAN, a LAN, or the like.

The storage unit 12 includes, for example, a random access memory (RAM), a read only memory (ROM), and the like. The storage unit 12 stores programs, various types of data, and the like for performing various control processes. For example, the storage unit 12 stores information such as a prediction model to be applied to an actual machine, a program for performing an optimization process, a prediction model in a state of being relearned using MR data, a prediction model in a state of not being relearned using MR data, a prediction result, an arithmetic equation of evaluation indexes, an evaluation result, training data, MR data, and the like.

The input unit 13 is constituted by an input device such as an operation button, a keyboard, a pointing device, and a microphone, for example. The input unit 13 is an input interface used by a user (for example, an operator in a local or remote location) to input an instruction.

The display unit 14 is constituted by a display device such as a liquid crystal display (LCD) and an electroluminescence (EL) display, for example.

The display unit 14 displays various types of information (for example, prediction results).

The control unit 15 is constituted by a processor such as a central processing unit (CPU) and a graphics processing unit (GPU). The control unit 15 implements various functions to be described later by executing the program stored in the storage unit 12.

Hereinafter, a functional configuration of the control unit 15 will be described. The control unit 15 functions as a prediction execution unit 151, a generating unit 152, an optimization unit 153, a cluster processing unit 154, and an assigning unit 155.

The prediction execution unit 151 is configured to acquire the predicted value of the target variable for the explanatory variable using the prediction model. For example, in a case where a prediction model is stored in the storage unit 12, the prediction execution unit 151 inputs an explanatory variable into the prediction model to acquire a predicted value of a target variable. For example, in a case where the prediction model is stored in another device, the prediction execution unit 151 transmits, via the communication unit 11, an explanatory variable to the device, and receives, from the device, a predicted value of a target variable.

The generating unit 152 is configured to transform training data to generate MR data. The training data is time series data indicating temporal changes in the explanatory variable and the target variable. The training data is the actually obtained data. The MR data is data for expanding variations in the training data. The generating unit 152 generates MR data for each of the explanatory variable and the target variable. Hereinafter, specific examples of the training data will be described.

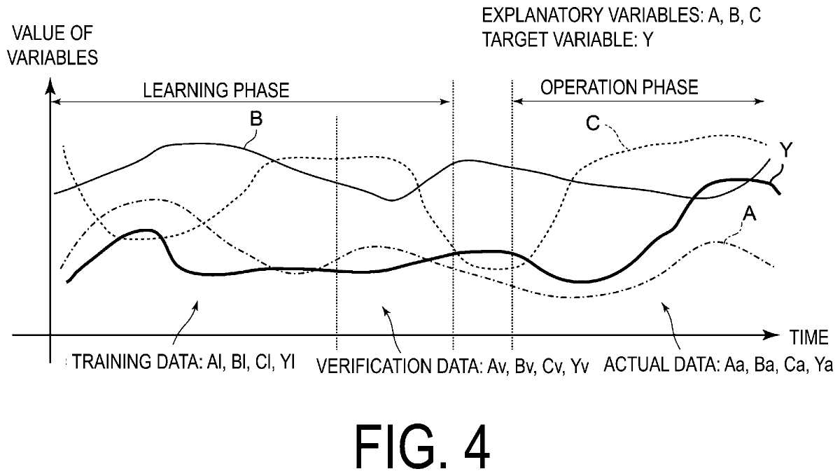

FIG. 4 is a diagram illustrating an example of time series data indicating temporal changes in an explanatory variable and a target variable. In this example, the explanatory variable is three variables A, B, and C, and the target variable is one variable Y. The training data may be “training data” obtained in a learning phase before actual operation has started, or may be “verification data”. Furthermore, the training data may be “actual data” obtained in a subsequent operation phase (after actual operation has started).

The “l” symbol added to the variables A, B, C, and Y indicates training data, the symbol “v” added to the variables A, B, C, and Y indicates verification data, and the symbol “a” added to the variables A, B, C, and Y indicates actual data. For example, training data items Al, Bl, Cl, and Yl are training data used at the time of initial learning of the prediction model. Verification data items Av, By, Cv, and Yv are training data used at the time of verification for verifying the performance of the prediction model before actual operation has started. The training data items Al, Bl, Cl, and Yl and the verification data items Av, By, Cv, and Yv are preferably training data acquired in different time zones. Actual data items Aa, Ba, Ca, and Ya are data acquired after actual operation has started. The actual data items Aa, Ba, Ca, and Ya may be training data used when updating the prediction model.

The MR data is virtual data obtained by processing the training data. The processing may be partial processing (for example, processing only some section of time series data). Specific examples of the MR data will be described later.

The optimization unit 153 is configured to optimize the prediction model. Specifically, the optimization unit 153 causes the prediction model to learn based on a first predicted value generated by the prediction model based on the training data, and a second predicted value generated by the prediction model based on the MR data generated by the generating unit 152. Here, evaluation scores indicating the accuracy of these predicted values will be described. A first evaluation score is a difference between a true value (a known target variable actually obtained) and the first predicted value. A second evaluation score is a difference between the target variable generated by the generating unit 152 and the second predicted value. The details of the evaluation score will be described later.

The cluster processing unit 154 is configured to generate a plurality of clusters by clustering the training data. The optimization unit 153 uses the plurality of clusters generated by the cluster processing unit 154 as training data to optimize the prediction model. That is, the optimization unit 153 optimizes the prediction model for each cluster by time-dividing the training data and using the clusters classified based on whether these data items are similar to each other.

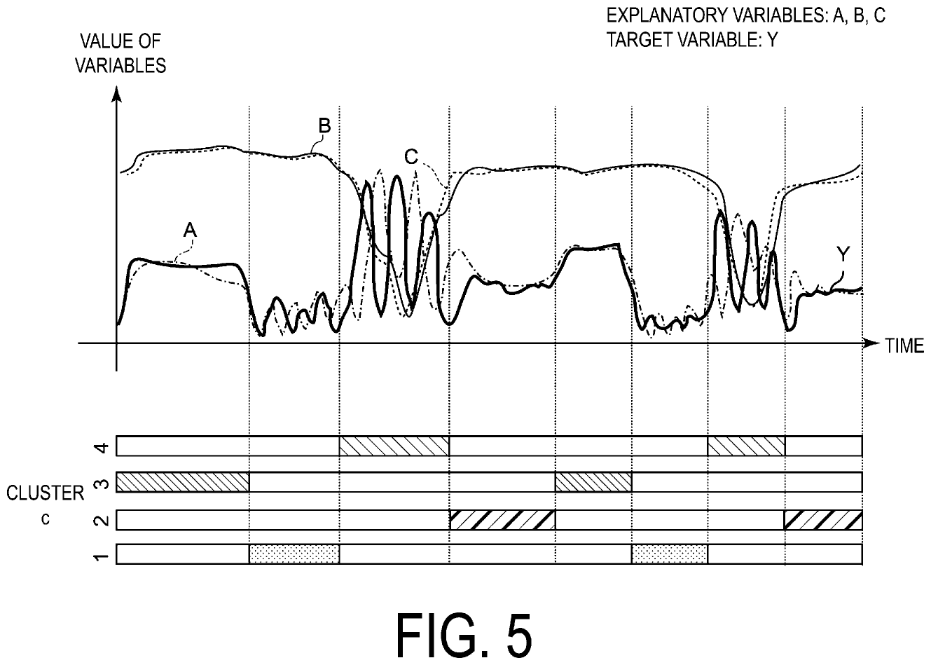

FIG. 5 is a conceptual diagram illustrating a clustering process executed by the model optimization device 100 according to the embodiment. As illustrated in FIG. 5, the time series data is time-divided as indicated by the dotted lines and clustered based on whether these data items are similar to each other. In the example of a cluster c illustrated in FIG. 5, they are classified into cluster 3, cluster 1, cluster 4, cluster 2, cluster 3, cluster 1, cluster 4, and cluster 2 in that order from the left side. Comparing the data corresponding to the same cluster number, it can be seen that waveforms are similar.

Note that, clustering may be performed in units of one explanatory variable (for example, whether they are similar by focusing only on A), or clustering may be performed in units of a plurality of explanatory variables (for example, whether A, B, and C are all similar). Clustering may be performed by focusing on the target variable Y.

Note that in FIG. 5, to visualize the clustering process, each cluster c is color-coded by hatching to show the correlation with the waveform. However, such processing is not essential. For example, the clustering process may only assign a code or identifier of the cluster c to each of the time division data items.

The assigning unit 155 is configured to assign a weighting to the second evaluation score indicating the accuracy of the second predicted value, which is the predicted value generated by the prediction model, based on the MR data generated by the generating unit 152. The assigning unit 155 may assign the weighting in accordance with at least one of the type of transformation processing, the amount of transformation, and target data of the MR data. The optimization unit 153 may optimize the prediction model based on the second evaluation score to which the weighting is assigned.

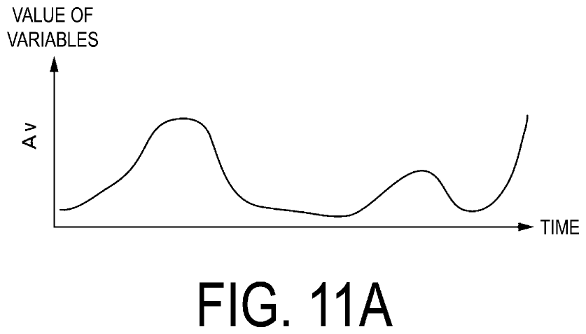

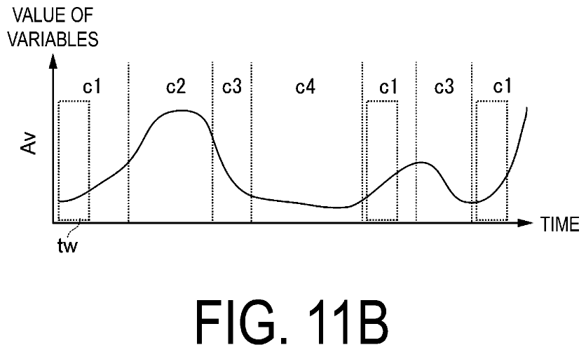

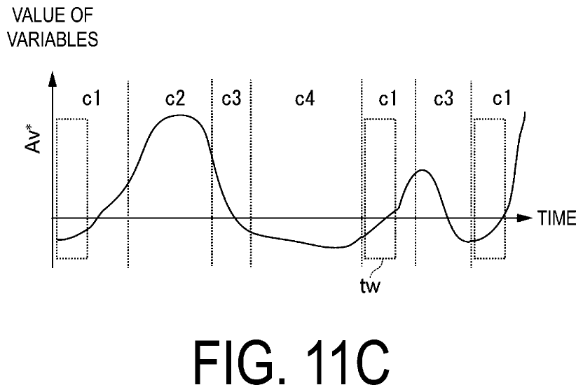

When the training data is time series data, the target data for the transformation processing of the MR data may be the cluster c to be transformed (for example, cluster 3), or a time t to be transformed (a time window tw illustrated in FIGS. 11B and 11C to be described later).

Further, the weighting may be performed in accordance with the results of analysis of frequency of occurrences, or may be performed in accordance with a condition set by the user based on knowledge (a determination in consideration of likelihood or validity). The frequency of occurrences may be, for example, the number of pieces of data classified into the same cluster c. In items such as the type of MR transformation processing, the amount of transformation, or target data, a relatively significant change pattern such as a change pattern that is likely to occur, a change pattern with a large effect on performance, or the like, may be assigned with a greater weight than a non-significant change pattern. By adjusting the second evaluation score by such a weighting, it is possible to improve prediction accuracy for a desired change pattern.

### Specific Examples of MR Data

Hereinafter, specific examples of the MR data generated by the generating unit 152 will be described. The generating unit 152 may generate the MR data by adding at least one of offset processing, slope change processing of the temporal change, time axis inversion processing, time constant change processing of the temporal change, filtering processing, noise addition processing, and transformation processing using generative adversarial networks (GAN) to the waveform indicating the temporal change of the training data.

Hereinafter, each type of transformation processing of the MR data will be described. Note that, in the following description, one explanatory variable A and one target variable Y will be described as representative examples for the sake of simplifying the description. However, the explanatory variable and the target variable are not limited to such examples. The number of explanatory variables and target variables may be one, or plural (for example, explanatory variables A, B, C, and D and target variables X and Y).

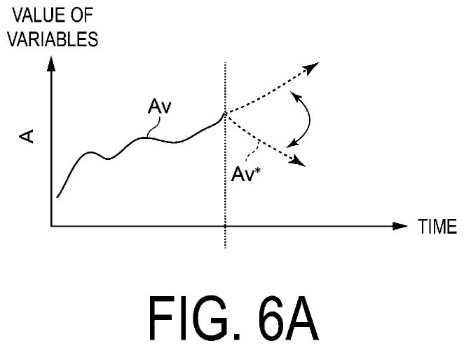

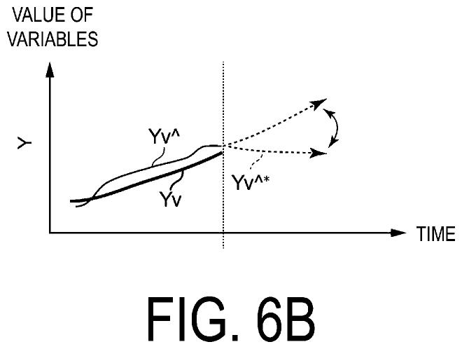

First, slope change processing of the temporal change will be described. FIG. 6A is a conceptual diagram illustrating an example (increase or decrease in consideration of slope) of MR data of an explanatory variable generated by the model optimization device 100 according to the embodiment. FIG. 6B is a conceptual diagram illustrating an example of a target variable (a second predicted value) acquired by the model optimization device 100 according to the embodiment based on the MR data illustrated in FIG. 6A.

As illustrated in FIG. 6A, in a case where an explanatory variable Av of verification data is acquired, the generating unit 152 extends the subsequent transition of the explanatory variable Av with a predetermined slope as indicated by the dashed line arrow, and generates an explanatory variable Av* of the MR data. The generating unit 152 may change the predetermined slope to generate three pieces of MR data, for example, an increasing pattern, a decreasing pattern, and a non-changing pattern, or may generate more MR data by increasing or decreasing the magnitude of the slope.

As illustrated in FIG. 6B, a target variable corresponding to the explanatory variable illustrated in FIG. 6A is obtained. First, a target variable Yv of the verification data for the explanatory variable Av of the verification data is acquired as training data. In addition, a first predicted value Yv\hat{ } is acquired as a target variable predicted by the prediction model based on the explanatory variable Av of the verification data. Furthermore, a second predicted value Yv\hat{ }* is acquired as a target variable predicted by the prediction model based on the explanatory variable Av* of the MR data.

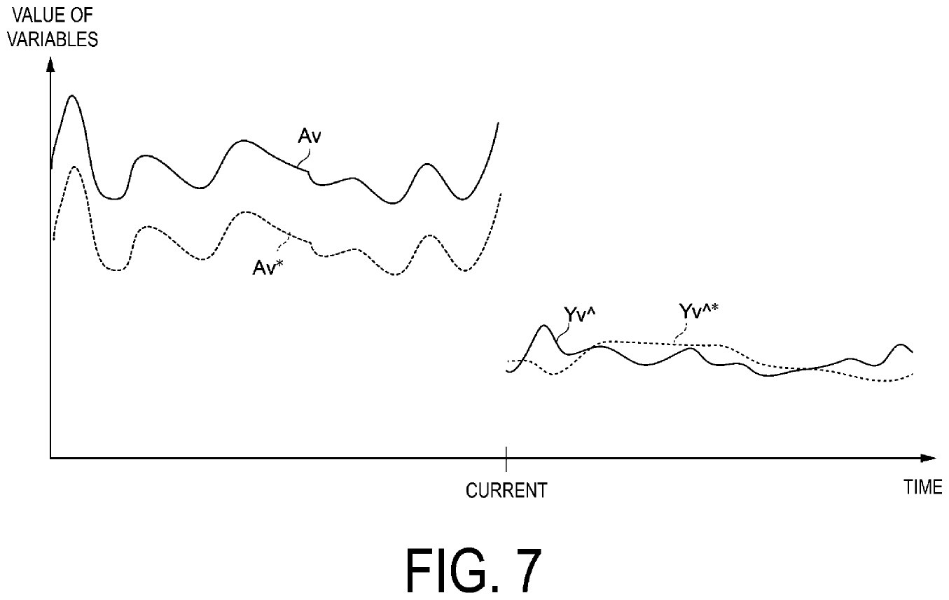

Next, offset processing will be described. FIG. 7 is a conceptual diagram illustrating an example (offset) of MR data generated by the model optimization device 100 according to the embodiment.

As illustrated in FIG. 7, in a case where the explanatory variable Av of the verification data is acquired, the generating unit 152 adds or subtracts a predetermined value to the explanatory variable Av to add an offset for some or all of the waveforms. In the example illustrated in FIG. 7, the generating unit 152 adds an offset in the negative direction with respect to all of the waveforms. Thus, an explanatory variable Av* of the MR data is generated. The generating unit 152 may change a predetermined value to generate, for example, more MR data.

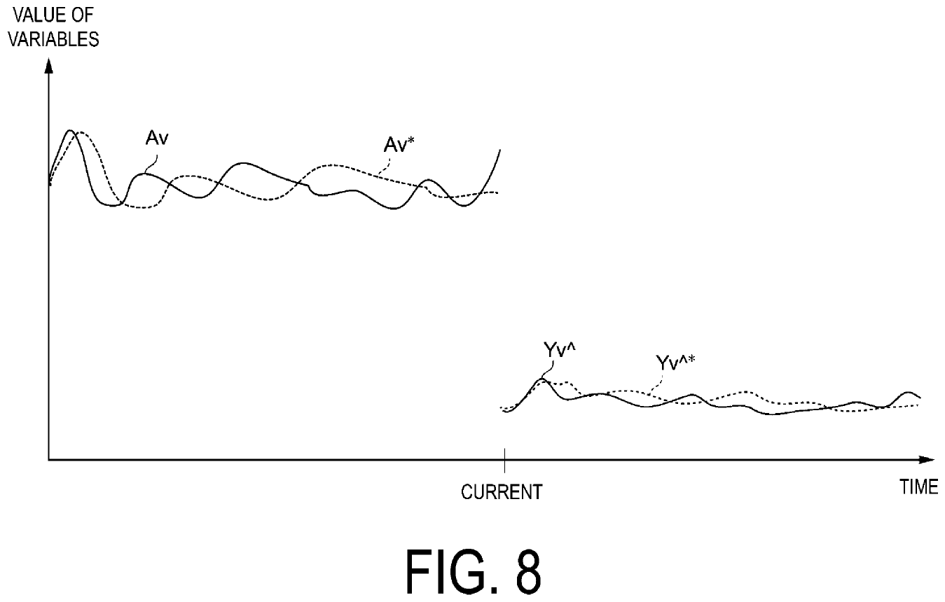

Next, time constant change processing of the temporal change will be described. FIG. 8 is a conceptual diagram illustrating an example (simulation of time constant change) of MR data generated by the model optimization device 100 according to the embodiment. Learning using such MR data is suitable, for example, in the case of improving prediction accuracy (robustness) of a prediction model when the reaction rate of a catalyst in a chemical plant changes.

As illustrated in FIG. 8, in a case where the explanatory variable Av of the verification data is acquired, the generating unit 152 changes the speed of the temporal change of the explanatory variable Av, that is, the time constant. Thus, an explanatory variable Av* of the MR data is generated. In the example illustrated in FIG. 8, the generating unit 152 slows down the speed of the temporal change, so that the change in MR data is gentle. The change in the time constant may be a process of generating a waveform in which the time constant is substantially changed by adding or subtracting the value of each plot rather than transformation processing that extends the time axis of the waveform. In this case, it is possible to prevent inconsistency of the time axis due to the transformation from occurring.

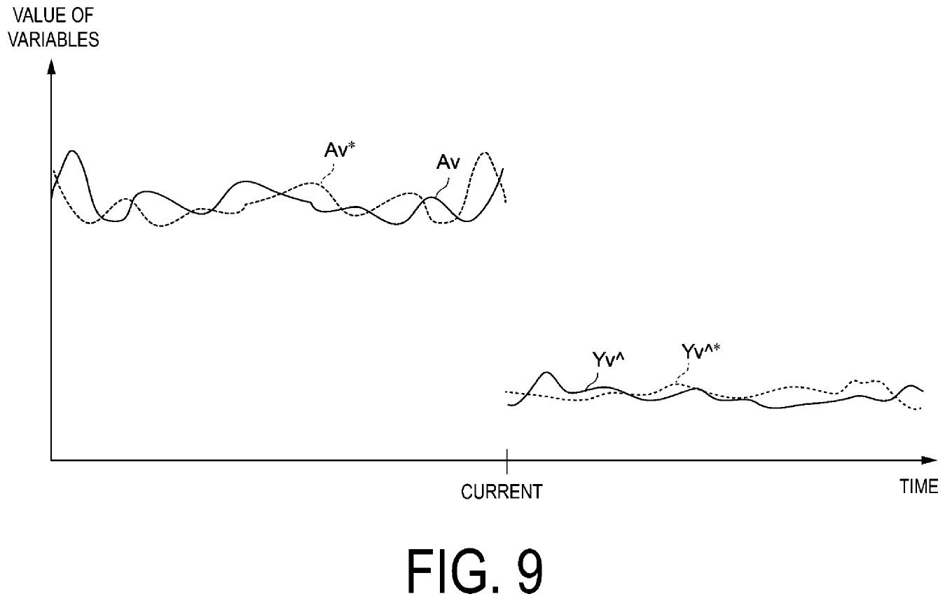

Next, time axis inversion processing will be described. FIG. 9 is a conceptual diagram illustrating an example (simulation of tendency change due to time inversion) of MR data generated by the model optimization device 100 according to the embodiment. Learning using such MR data is suitable in the case of improving prediction accuracy (robustness) of a prediction model when the opposite motion occurs. This is advantageous when the explanatory variables are likely to change in contrast, for example, start and stop.

As illustrated in FIG. 9, in a case where the explanatory variable Av of the verification data is acquired, the generating unit 152 reverses the sequence order of the time series data of the explanatory variable Av. Thus, an explanatory variable Av* of the MR data is generated. Referring to FIG. 9, it can be seen that, for the waveform of the explanatory variable Av of the verification data, the waveform of the explanatory variable Av* of the MR data is in a left-right inverted state.

Note that in the examples illustrated in FIGS. 7 to 9, a first predicted value Yv\hat{ } is acquired as a target variable predicted by the prediction model based on the explanatory variable Av of the verification data, as in the examples illustrated in FIGS. 6A and 6B. Furthermore, a second predicted value Yv\hat{ }* is acquired as a target variable predicted by the prediction model based on the explanatory variable Av* of the MR data. Note that the target variable Yv of the verification data for the explanatory variable Av of the verification data is not illustrated.

Next, filtering processing, noise addition processing, and transformation processing using a GAN will be described. For example, when white noise is added and when white noise is removed, these may be MR data because the average values are the same. Thus, such MR may be used to generate MR data. Furthermore, in generating the MR data, a technique for generating new data by transformation processing using a GAN generation network may be applied. According to the learning using such MR data, it is possible to improve the robustness with respect to the magnitude of the slope change processing of the temporal change, unlike the improvement of the robustness with respect to the slope.

The above-described MR data can be combined as appropriate. Robustness can be further improved by combining the above-described MR data and using it for optimizing the prediction model.

MR data may be generated by transforming into some clusters. That is, MR data may be generated by transforming in cluster units. Hereinafter, examples thereof will be described.

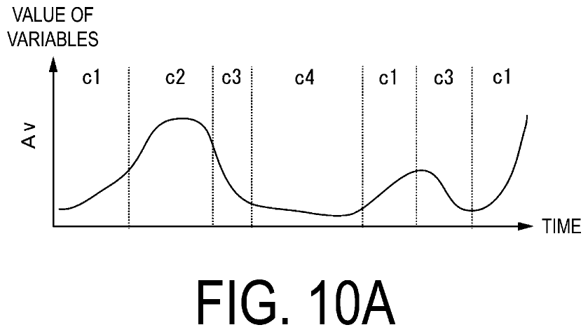

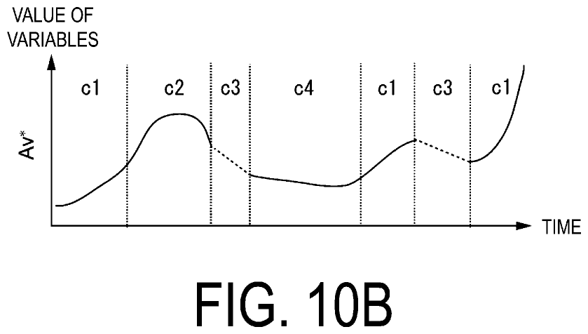

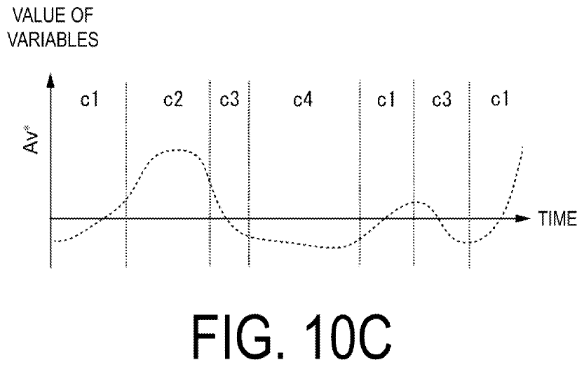

FIG. 10A is a conceptual diagram illustrating an example of verification data used by the model optimization device 100 according to the embodiment. FIG. 10B is a conceptual diagram illustrating an example of MR data generated from the verification data illustrated in FIG. 10A. FIG. 10C is a conceptual diagram illustrating an example of MR data generated from the verification data illustrated in FIG. 10A.

As illustrated in FIG. 10A, when time series verification data Av is obtained, clustering is performed to classify the data into clusters c1 to c4. Here, as illustrated in FIG. 10B, the cluster c3 may be processed so as to have a gentle slope. In this case, the generating unit 152 may transform the other clusters c1, c2, and c4 in response to transformation of the cluster c3. For example, the generating unit 152 may adjust a cluster other than the cluster c3 by an offset to continuously connected to a transformed cluster c3. As a result, it is possible to prevent the transformation of the cluster c3 from causing discontinuous values or excessively fluctuating portions in the waveform.

Also, as illustrated in FIG. 10C, offsets may be added for all clusters c1 to c4. In this way, transformation can be applied to some or all of the clusters to generate MR data.

The MR data may be subject to processing of time series data of some or all times. Here, the time concept in processing may be set as a subordinate concept in the cluster, or may be set as a separate concept from the cluster without clustering. For example, also in the weighting, the weights may be changed between the first half three minutes and the second half three minutes of the cluster, or the weights may be changed between five minutes with time series data and times other than the five minutes.

Hereinafter, a time window tw when the time is the processing target will be described. FIG. 11A is a conceptual diagram illustrating an example of a process of generating MR data by the model optimization device 100 according to the embodiment. FIG. 11B is a conceptual diagram illustrating an example of a process of generating MR data by the model optimization device 100 according to the embodiment. FIG. 11C is a conceptual diagram illustrating an example of a process of generating MR data by the model optimization device 100 according to the embodiment.

First, as illustrated in FIG. 11A, it is assumed that an explanatory variable Av of verification data is obtained. In this case, as illustrated in FIG. 11B, the cluster processing unit 154 performs a clustering process to classify the time series data into clusters c1 to c4. Here, the optimization unit 153 may set the time window tw as a transformation target for a predetermined time of the cluster c1 (for example, from two seconds after the start of the cluster c1 for 10 seconds).

Furthermore, the optimization unit 153 may add an offset to the explanatory variable Av in the time window tw. The optimization unit 153 may adjust the waveform portion other than the time window tw by scaling with the apex fixed so as to connect to the explanatory variable Av after adding the offset. Thus, an explanatory variable Av* of the MR data illustrated in FIG. 11C is generated.

Specific examples of the MR data have been described above. Note that the storage unit 12 of the model optimization device 100 may be configured to store information regarding MR data. The information regarding the MR data may be MR data, or may be additional information indicating the type of transformation processing, the amount of transformation, target data, and the like in generating the MR data.

The information regarding the MR data stored in the storage unit 12 may be updated in accordance with the results of the optimization. In this case, the storage unit 12 can store more appropriate MR data. Note that the storage unit 12 may further store information regarding training data, a weighting assigned once, an arithmetic equation used for evaluation to be described later, various predicted values, various evaluation scores to be described later, evaluation results to be described later, results of necessity determination to be described later, and the like. According to such a configuration, for example, information regarding MR such as the data used to generate past MR data and the generated MR data can be read from the storage unit 12 and reused.

### Optimization Based on Performance Evaluation

Hereinafter, optimization based on performance evaluation of the prediction model by the model optimization device 100 according to some embodiments will be described. This performance evaluation is performed when considering the effectiveness of relearning using MR data, the need for updating the prediction model or updating the weighting, and the like, and when applying the update.

The optimization unit 153 is configured to evaluate the performance of the prediction model based on a first evaluation score indicating the accuracy of a first predicted value and a second evaluation score indicating the accuracy of a second predicted value. Furthermore, the optimization unit 153 acquires, as a third evaluation score, the first evaluation score when the prediction model after relearning based on the MR data is evaluated using the training data (actual data) acquired after actual operation has started. The optimization unit 153 acquires, as a fourth evaluation score, the first evaluation score when the prediction model before relearning based on the MR data is evaluated using the training data (actual data) acquired after actual operation has started. The optimization unit 153 acquires, as a fifth evaluation score, the second evaluation score when the prediction model after relearning based on the MR data is evaluated using the MR data based on the training data (actual data) acquired after actual operation has started. The optimization unit 153 acquires, as a sixth evaluation score, the second evaluation score when the prediction model before relearning based on the MR data is evaluated using the MR data based on training data (actual data) acquired after actual operation has started. Note that updating the prediction model is performed by relearning the prediction model based on the training data (actual data) acquired after actual operation has started and/or the MR data.

The optimization unit 153 may be configured to determine the necessity of at least one of updating the prediction model and updating the weighting assigned to the second evaluation score in accordance with the evaluation results based on the third evaluation score, the fourth evaluation score, the fifth evaluation score, and the sixth evaluation score. The result of the necessity determination may be presented to a user as reference information. In this case, the user may manually update the prediction model and the weighting. Furthermore, the update process of the prediction model or the update process of the weighting used by the model optimization device 100 may be automatically executed based on the result of the necessity determination instead of the manual operation of the user.

The optimization unit 153 may be configured to execute at least one of a process of applying the update to the prediction model and a process of updating the weighting assigned by the assigning unit 155 in accordance with the result of the necessity determination. In this case, the update of the prediction model and the update of the weighting are automatically executed in accordance with the result of the necessity determination, and thus the burden on the user can be reduced.

The optimization unit 153 may be configured to calculate an evaluation index based on the square of the first evaluation score and a sum of the squares of the second evaluation score, to which the weighting is assigned, indicating the accuracy of the second predicted value and optimize the prediction model based on the calculated evaluation index. The evaluation index is J calculated using Equation (1) below, for example. Note that Equation (1) is an equation for calculating an evaluation index for the entire time series data.

J=(y\hat{ }−y)²Σw(c,m,s){(y\hat{ }MR(c,m,s)−yMR(c,m,s))²+(y\hat{ }MR−(c,m,s)−yMR−(c,m,S))²} (1)

In Equation (1), y\hat{ } indicates a first predicted value, and y indicates a true value, that is, a target variable of the training data. y\hat{ }MR indicates a second predicted value and yMR indicates a MR true value. The MR true value is a value obtained by adding a difference due to the transformation of MR to the true value, that is, y, which is the training data. The reference sign MR indicates the processed portion of the MR data, and the reference sign MR− indicates the unprocessed portion of the MR data. (c, m, s) means that the elements of the weights w, y\hat{ }MR, and y\hat{ }MR− are denoted by the cluster C, m indicating the type or magnitude of MR, and s indicating the time window tw. That is, there are a weight w, a second predicted value y\hat{ }MR, and y\hat{ }MR− for each combination of elements. In Equation (1), y\hat{ }−y corresponds to the first evaluation score, and y\hat{ }MR(c, m, s)−yMR(c, m, s) and y\hat{ }MR−(c, m, s)−yMR−(c, m, s) correspond to the second evaluation score.

Σ indicates that the sum is calculated for all element combinations. For example, when a cluster c1 is processed, the unprocessed portions of the MR data are other clusters c2, c3 . . . cz (where z is any numerical value).

For example, the optimization unit 153 may perform optimization by causing the prediction model to learn so that the performance of the prediction model is increased in accordance with the evaluation index. It can be said that, if the evaluation index is J, the smaller the evaluation index, the higher the performance of the prediction model. On the other hand, if the evaluation index is the reciprocal of J, the smaller the evaluation index, the lower the performance of the prediction model. In other words, the relationship between the performance of the prediction model and the evaluation index depends on the definition. Thus, as long as the learning is performed such that the performance of the prediction model is increased, a configuration in which the evaluation index is increased may be used, or a configuration in which the evaluation index is decreased may be used.

The optimization unit 153 may be configured to calculate an evaluation index for each of combinations of the type of transformation processing, the amount of transformation, and target data of the MR data, and extract one or more combinations evaluated as having a low performance of the prediction model. The one or more combinations may be a predetermined number of combinations (for example, N selected from the lowest order of evaluation (where N is a natural number set by the user)) evaluated as having a low performance of the prediction model. Further, the one or more combinations may be a combination selected depending on whether the evaluation index is equal to or less than the reference value.

The extraction of the upper N combinations by the optimization unit 153 is performed, for example, by decomposing each combination of c, m, and s from the results obtained by calculating Equation (1) described above and extracting the N combinations from them. Note that the optimization unit 153 may be configured so that, instead of calculating the total value as in Equation (1) described above, a subscript of combination is added to J like J_{cms}, and N or more equations obtained by modifying the combination of cms are created, and the upper N elements are extracted from the equations.

The optimization unit 153 may acquire training data corresponding to the target data of the extracted one or more combinations, input the acquired training data into the generating unit 152, and cause the generating unit 152 to generate MR data by transformation processing corresponding to the type of transformation processing and the amount of transformation of the one or more combinations. Also, the optimization unit 153 may be configured to cause the prediction model to perform relearning using the generated MR data. In this case, the prediction model performs relearning on data having a low performance, and thus the prediction accuracy is improved.

Here, a specific example of the results and necessity determination of the performance evaluation of the prediction model by the optimization unit 153 will be described. The necessity determination is a determination as to whether updating the prediction model or updating the weighting is necessary using actual data acquired after actual operation has started. In the evaluation in the determination, the actual data acquired after actual operation has started and the MR data are used to evaluate the current prediction model (both the presence or absence of relearning based on the MR data).

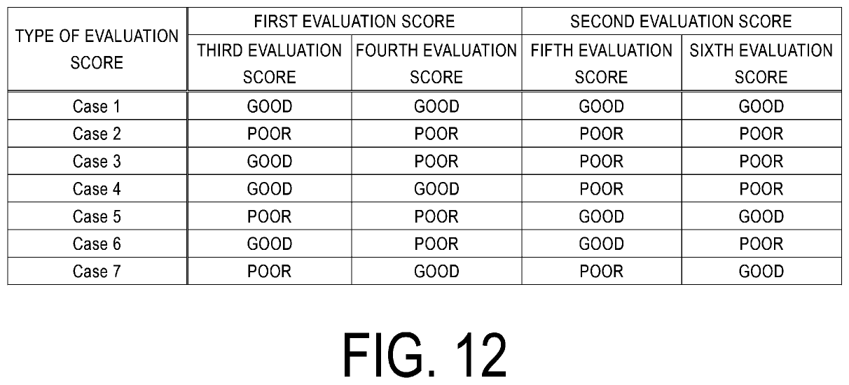

FIG. 12 is a schematic diagram illustrating a specific example of evaluation results using the model optimization device 100 according to the embodiment. In FIG. 12, seven examples (Case 1 to Case 7) are shown as examples of evaluation results for the third evaluation score, the fourth evaluation score, the fifth evaluation score, and the sixth evaluation score, and the determination results of the performance evaluation are indicated by “GOOD” for a good result and “POOR” for a poor result. Note that the optimization unit 153 may have a configuration in which the quality of performance is determined quantitatively instead of the configuration in which the quality of performance is determined by binarizing as illustrated in FIG. 12.

Here, the third evaluation score may be a value obtained by calculating the evaluation index J=(y\hat{ }−y)² in the prediction model after relearning based on the MR data. The fourth evaluation score may be a value obtained by calculating the evaluation index J=(y\hat{ }−y)² in the prediction model before relearning based on the MR data. The fifth evaluation score may be a value obtained by calculating the evaluation index J=Σw(c, m, s){(y\hat{ }MR(c, m, s) −yMR(c, m, s))²+(y\hat{ }MR−(c, m, s)−yMR−(c, m, s))²} in the prediction model after relearning based on the MR data. The sixth evaluation score may be a value obtained by calculating the evaluation index J=Σw(c, m, s){(y\hat{ }MR(c, m, s)−yMR(c, m, s))²+(y\hat{ }MR−(c, m, s)−yMR−(c, m, s))²} in the prediction model before relearning based on the MR data.

First, in Case 1, all of the evaluation scores are good. In this case, because performance is good regardless of the presence or absence of relearning based on the MR data, it may be determined that updating the prediction model is unnecessary. In Case 2, because all performance is poor, it is thought that actual data completely different from the learned data or the MR data is input. In this case, updating the prediction model may be determined to be necessary, or may be considered an outlier and determined to be unnecessary. In Case 3, only the third evaluation score is good, and the other evaluation scores are poor. In this case, it can be seen that relearning using the MR data was effective. It may also be considered to reflect the results in weight updates.

In Case 4, it can be seen that the prediction accuracy has dropped on the MR data generated from the actual data, and therefore the need for updating the prediction model may be considered. In Case 5, for the actual data, the results are poor regardless of the presence or absence of relearning based on the MR data, so that it is conceivable that unlearned actual data is input. Thus, it may be determined that the update of the prediction model is necessary. Because Case 6 has good results of the third evaluation score and the fifth evaluation score, it may be determined that the update of the prediction model is unnecessary. In this case, the effectiveness of relearning based on MR data can also be checked. In Case 7, the results of the third evaluation score and the fifth evaluation score are poor, so that it can be seen that relearning using MR data is not successful. Thus, it may be determined that the update of the weight is necessary.

### Flow of Optimization Process

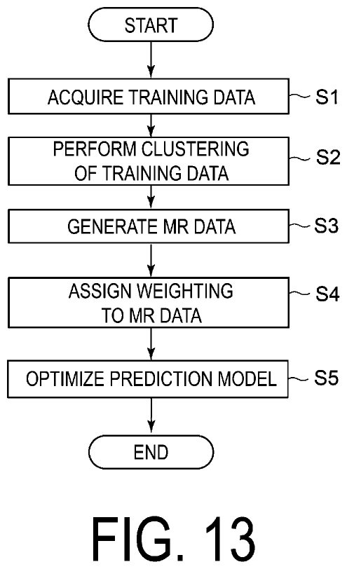

Hereinafter, the flow of the optimization process of the prediction model by the model optimization device 100 according to the embodiment will be described with reference to FIGS. 13 to 15. Note that the model optimization process described below may be automatically executed by the model optimization device 100, or may be executed by manual operation of an operator. Also, it is assumed that the prediction model has already been learned based on training data. Thus, the optimization process is a process for optimizing the learned prediction model.

FIG. 13 is a flowchart illustrating an optimization process by the model optimization device 100 according to the embodiment. This process may be performed before learning based on MR data, or may be performed after learning based on MR data. Furthermore, this process may be performed before actual operation has started, or may be performed after actual operation has started.

As illustrated in FIG. 13, the model optimization device 100 acquires training data via the communication unit 11 (step S1). The cluster processing unit 154 of the model optimization device 100 performs a clustering process on training data (step S2). The generating unit 152 of the model optimization device 100 generates MR data from the training data (step S3). The assigning unit 155 of the model optimization device 100 performs a weighting on the MR data (step S4). The optimization unit 153 of the model optimization device 100 optimizes the prediction model (step S5). This optimization may be performed based on the above-described evaluation index, or may be performed based on other evaluation criteria.

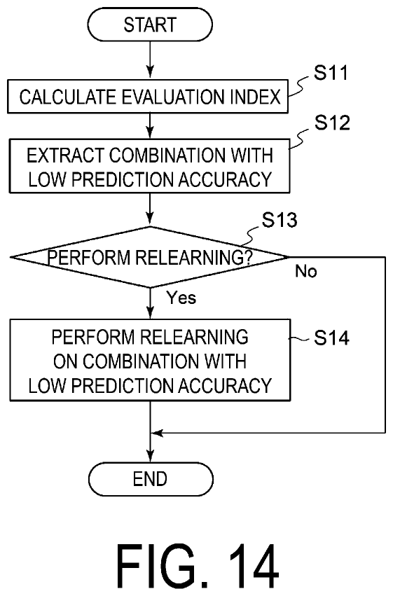

FIG. 14 is a flowchart illustrating an optimization process by the model optimization device 100 according to the embodiment. This process is performed when a more detailed model evaluation is performed and the prediction model is relearned. As illustrated in FIG. 14, the model optimization device 100 performs the same processing as the evaluation of the performance of the prediction model illustrated in FIG. 13, and the optimization unit 153 calculates the evaluation index (step S11).

The optimization unit 153 extracts a combination with low prediction accuracy from evaluation results based on the evaluation index (step S12). The optimization unit 153 calculates the evaluation index J for the entire time series data, and extracts one or more combinations of the type of transformation processing, the amount of transformation, and target data (target cluster and target time) of the MR data with low prediction accuracy. Note that the optimization unit 153 may extract the MR data with low prediction accuracy by focusing on only one or more of the type of transformation processing, the amount of transformation, and the target data.

Here, it is determined whether to perform the relearning (step S13). For example, the model optimization device 100 may determine whether to perform relearning in response to an input instruction by an operator. In this case, the model optimization device 100 may display evaluation results of MR data with low prediction accuracy so that the operator can determine whether to perform the relearning. Furthermore, the model optimization device 100 may compare the evaluation results with the threshold value to determine whether to perform the relearning. Note that this step S13 may be omitted, and the relearning may necessarily be performed, or the relearning may be performed only by evaluating the performance. When the relearning is not performed (step S13; No), the model optimization device 100 ends the process.

When the relearning is performed (step S13; Yes), the model optimization device 100 causes the prediction model to perform relearning on the MR data of the combination with low prediction accuracy (step S14).

Specifically, the model optimization device 100 acquires training data corresponding to the target data of the extracted one or more combinations, inputs the acquired training data into the generating unit 152, and causes the generating unit 152 to generate MR data by transformation processing corresponding to the type of transformation processing and the amount of transformation of the one or more combinations. In addition, the optimization unit 153 causes the prediction model to perform relearning using the generated MR data. Note that the calculation of the evaluation index and the execution of relearning may be performed repeatedly until sufficient robustness can be ensured.

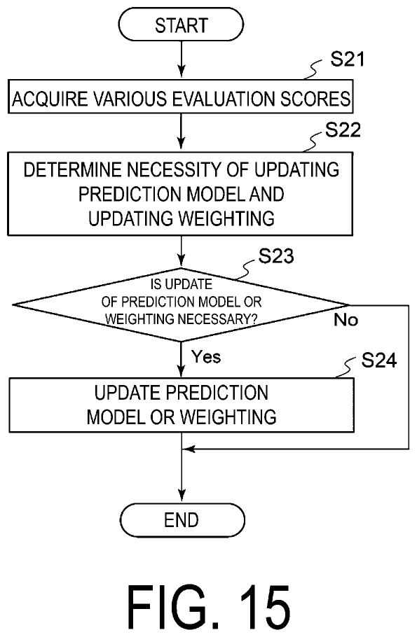

FIG. 15 is a flowchart illustrating an optimization process by the model optimization device 100 according to the embodiment. This process is performed when performance evaluation of the prediction model is performed using the training data (actual data) acquired after actual operation has started.

This process is performed, for example, when examining whether the performance of the prediction model is sufficient in a case where a change in actual data occurs due to deterioration over time or the like, and determining whether updating the prediction model or updating the weighting is necessary.

First, the optimization unit 153 performs performance evaluation of the prediction model using the actual data and the MR data, and acquires various evaluation scores (step S21). The various evaluation scores are the third evaluation score, the fourth evaluation score, the fifth evaluation score, and the sixth evaluation score. As a result, a result of any of the Case 1 to Case 7 illustrated in FIG. 12 is obtained, for example. Note that in FIG. 12, only seven types are illustrated as representative examples, but there may be 16 types as the evaluation results.

The optimization unit 153 determines the necessity of updating the prediction model and updating the weighting based on the various evaluation scores (step S22). The optimization unit 153 determines whether updating the prediction model or the weighting is necessary as a result of the necessity determination (step S23). When the update is determined to be unnecessary (step S23; No), the process ends. On the other hand, if the update is determined to be necessary (step S23; Yes), the optimization unit 153 updates the prediction model or updates the weighting assigned by the assigning unit 155 (step S24).

The present disclosure is not limited to the embodiments described above and also includes a modification of the above-described embodiments and a combination of a plurality of embodiments as appropriate.

### SUMMARY

The details described in each embodiment can be understood as follows, for example.

(1) According to the present disclosure, there is provided a model optimization device (100) that optimizes a prediction model configured to generate predicted values of a target variable for an explanatory variable. The model optimization device (100) includes: a generating unit (152) configured to generate expanded MR data by transforming training data; and an optimization unit (153) configured to cause the prediction model to learn and optimize the prediction model based on a first predicted value generated by the prediction model based on the training data, and a second predicted value generated by the prediction model based on the MR data.

According to the above configuration, even in a case where the prediction model is not sufficiently learned with the training data alone, the MR data is used to learn the prediction model, and thus the robustness of the prediction model can be improved.

(2) In some embodiments, in the configuration described in (1) above, the training data is time series data indicating temporal changes in the explanatory variable and the target variable.

For example, in facilities such as plants, power generation devices, and the like, it may be necessary to control the operation of various devices or to create an operation plan for the facility. In this case, it is conceivable to use time series data of measured values of various sensors in operation control and the creation of an operation plan. In this regard, according to the above configuration, the prediction model is learned with the time series data as training data. Thus, the prediction results of the prediction model are suitable for use in operation control and the creation of an operation plan.

(3) In some embodiments, in the configuration described in (2) above, the generating unit (152) generates the MR data by adding at least one of offset processing, slope change processing of the temporal change, time axis inversion processing, time constant change processing of the temporal change, filtering processing, and noise addition processing to a waveform indicating temporal change of the training data.

According to the above configuration, since MR data obtained by adding at least one type of transformation processing that is often performed as a transformation example of time series data is used for learning, it is possible to improve the robustness of the prediction model that predicts a target variable for an explanatory variable that changes in time.

(4) In some embodiments, in the configuration described in any one of (1) to (3) above, the model optimization device further includes a cluster processing unit (154) configured to generate a plurality of clusters by clustering the training data, in which the optimization unit (153) optimizes the prediction model by using the plurality of clusters as the training data.

According to the above configuration, it is possible to classify similar training data by clustering and optimize the prediction model for each cluster.

(5) In some embodiments, in the configuration described in any one of (1) to (4) above, the model optimization device further includes an assigning unit (155) configured to assign a weighting to a second evaluation score indicating accuracy of the second predicted value in accordance with at least one of a type of transformation processing, an amount of transformation, and target data of the MR data, in which the optimization unit (153) optimizes the prediction model based on the second evaluation score to which the weighting is assigned.

According to the above configuration, it is possible to improve prediction accuracy for a desired change pattern by adjusting by weighting.

(6) In some embodiments, in the configuration described in any one of (1) to (5) above, the optimization unit (153) is configured to evaluate performance of the prediction model based on a first evaluation score indicating accuracy of the first predicted value and a second evaluation score indicating accuracy of the second predicted value, and the optimization unit (153) is further configured to: acquire, as a third evaluation score, the first evaluation score when the prediction model after learning based on the MR data is evaluated using the training data acquired after actual operation has started; acquire, as a fourth evaluation score, the first evaluation score when the prediction model before learning based on the MR data is evaluated using the training data acquired after the actual operation has started; acquire, as a fifth evaluation score, the second evaluation score when the prediction model after learning based on the MR data is evaluated using the MR data based on the training data acquired after the actual operation has started; and acquire, as a sixth evaluation score, the second evaluation score when the prediction model before learning based on the MR data is evaluated using the MR data based on the training data acquired after the actual operation has started.

According to the above configuration, it is possible to determine whether it is better to update the prediction model or the weighting.

(7) In some embodiments, in the configuration described in (6) above, the optimization unit (153) determines a necessity of at least one of updating the prediction model and updating a weighting assigned to the second evaluation score in accordance with evaluation results based on the third evaluation score, the fourth evaluation score, the fifth evaluation score, and the sixth evaluation score.

According to the above configuration, it is possible to determine the necessity of at least one of whether an improvement in the performance of the prediction model can be expected by updating the prediction model and whether an improvement in the learning capacity of the prediction model can be expected by updating the weighting.

(8) In some embodiments, in the configuration described in (7) above, the model optimization device (100) further includes an assigning unit (155) configured to assign the weighting to the second evaluation score in accordance with at least one of a type of transformation processing, an amount of transformation, and target data of the MR data, in which the optimization unit (153) executes at least one of processing for updating the prediction model and processing for updating the weighting assigned by the assigning unit (155) in accordance with a result of the necessity determination.

According to the above configuration, the update of the prediction model and the update of the weighting are automatically executed in accordance with the result of the necessity determination, and thus the burden on the user can be reduced.

(9) In some embodiments, in the configuration described in any one of (1) to (8) above, the model optimization device (100) further includes a storage unit (12) configured to store information regarding the MR data.

According to the above configuration, for example, information regarding MR such as the data used to generate past MR data and the generated MR data can be read from the storage unit (12) and reused.

(10) In some embodiments, in the configuration described in any one of (1) to (9) above, the optimization unit (153) calculates an evaluation index based on a square of a first evaluation score indicating accuracy of the first predicted value and a sum of squares of a second evaluation score, to which a weighting is assigned, indicating accuracy of the second predicted value and optimizes the prediction model based on the evaluation index.

According to the above configuration, the balance between the first evaluation score and the second evaluation score in the evaluation index used in the optimization can be adjusted by weighting. In this way, it is possible to prevent overlearning due to learning based on MR data for expanding training data.

(11) In some embodiments, in the configuration described in (10) above, the optimization unit (153) calculates the evaluation index for each of combinations of a type of transformation processing, an amount of transformation, and target data of the MR data, and extracts one or more combinations evaluated as having a low performance of the prediction model.

According to the above configuration, it is possible to know what kind of data the prediction model has a low performance. Thus, the extraction results can be used for relearning.

(12) In some embodiments, in the configuration described in (11) above, the optimization unit (153) is configured to acquire the training data corresponding to the target data of the extracted one or more combinations, input the acquired training data to the generating unit (152), cause the generating unit (152) to generate the MR data by transformation processing corresponding to the type of the transformation processing and the amount of transformation of the one or more combinations, and cause the prediction model to perform relearning using the generated MR data.

According to the above configuration, since the prediction model is relearned for data having a low performance, the prediction accuracy (robustness) of the prediction model is improved.

(13) According to the present disclosure, there is provided a model optimization method for optimizing a prediction model configured to generate predicted values of a target variable for an explanatory variable. The model optimization method includes: generating expanded MR data by transforming training data; and causing the prediction model to learn and optimizing the prediction model based on a first predicted value generated by the prediction model based on the training data, and a second predicted value generated by the prediction model based on the MR data.

According to the above method, even in a case where the prediction model is not sufficiently learned with the training data alone, the MR data is used to learn the prediction model, and thus the robustness of the prediction model can be improved.

(14) According to the present disclosure, there is provided a program for causing a computer to optimize a prediction model configured to generate predicted values of a target variable for an explanatory variable. The program causes the computer to execute: generating expanded MR data by transforming training data; and causing the prediction model to learn and optimizing the prediction model based on a first predicted value generated by the prediction model based on the training data, and a second predicted value generated by the prediction model based on the MR data.

According to the above program, even in a case where the prediction model is not sufficiently learned with the training data alone, the MR data is used to learn the prediction model, and thus the robustness of the prediction model can be improved.

While preferred embodiments of the disclosure have been described as above, it is to be understood that variations and modifications will be apparent to those skilled in the art without departing from the scope and spirit of the disclosure. The scope of the disclosure, therefore, is to be determined solely by the following claims.

1. A model optimization device that optimizes a prediction model configured to generate predicted values of a target variable for an explanatory variable, the model optimization device comprising:
a generating unit configured to generate expanded MR data by transforming training data; and
an optimization unit configured to cause the prediction model to learn and optimize the prediction model based on a first predicted value generated by the prediction model based on the training data, and a second predicted value generated by the prediction model based on the MR data.

2. The model optimization device according to claim 1, wherein
the training data is time series data indicating temporal changes in the explanatory variable and the target variable.

3. The model optimization device according to claim 2, wherein
the generating unit generates the MR data by adding at least one of offset processing, slope change processing of the temporal change, time axis inversion processing, time constant change processing of the temporal change, filtering processing, noise addition processing, and transformation processing using a GAN to a waveform indicating temporal change of the training data.

4. The model optimization device according to claim 1, further comprising:
a cluster processing unit configured to generate a plurality of clusters by clustering the training data,
wherein the optimization unit optimizes the prediction model by using the plurality of clusters as the training data.

5. The model optimization device according to claim 1, further comprising:
an assigning unit configured to assign a weighting to a second evaluation score indicating accuracy of the second predicted value in accordance with at least one of a type of transformation processing, an amount of transformation, and target data of the MR data,
wherein the optimization unit optimizes the prediction model based on the second evaluation score to which the weighting is assigned.

6. The model optimization device according to claim 1, wherein
the optimization unit is configured to evaluate performance of the prediction model based on a first evaluation score indicating accuracy of the first predicted value and a second evaluation score indicating accuracy of the second predicted value, and
the optimization unit is further configured to:
acquire, as a third evaluation score, the first evaluation score when the prediction model after learning based on the MR data is evaluated using the training data acquired after actual operation has started;
acquire, as a fourth evaluation score, the first evaluation score when the prediction model before learning based on the MR data is evaluated using the training data acquired after the actual operation has started;
acquire, as a fifth evaluation score, the second evaluation score when the prediction model after learning based on the MR data is evaluated using the MR data based on the training data acquired after the actual operation has started; and
acquire, as a sixth evaluation score, the second evaluation score when the prediction model before learning based on the MR data is evaluated using the MR data based on the training data acquired after the actual operation has started.

7. The model optimization device according to claim 6, wherein
the optimization unit determines a necessity of at least one of updating the prediction model and updating a weighting assigned to the second evaluation score in accordance with evaluation results based on the third evaluation score, the fourth evaluation score, the fifth evaluation score, and the sixth evaluation score.

8. The model optimization device according to claim 7, further comprising:
an assigning unit configured to assign the weighting to the second evaluation score in accordance with at least one of a type of transformation processing, an amount of transformation, and target data of the MR data,
wherein the optimization unit executes at least one of processing for updating the prediction model and processing for updating the weighting assigned by the assigning unit in accordance with a result of the necessity determination.

9. The model optimization device according to claim 1, further comprising a storage unit configured to store information regarding the MR data.

10. The model optimization device according to claim 1, wherein
the optimization unit calculates an evaluation index based on a square of a first evaluation score indicating accuracy of the first predicted value and a sum of squares of a second evaluation score, to which a weighting is assigned, indicating accuracy of the second predicted value and optimizes the prediction model based on the evaluation index.

11. The model optimization device according to claim 10, wherein
the optimization unit calculates the evaluation index for each of combinations of a type of transformation processing, an amount of transformation, and target data of the MR data, and extracts one or more combinations evaluated as having a low performance of the prediction model.

12. The model optimization device according to claim 11, wherein
the optimization unit is configured to:
acquire the training data corresponding to the target data of the extracted one or more combinations;
input the acquired training data to the generating unit;
cause the generating unit to generate the MR data by transformation processing corresponding to the type of the transformation processing and the amount of transformation of the one or more combinations; and
cause the prediction model to perform relearning using the generated MR data.

13. A model optimization method for optimizing a prediction model configured to generate predicted values of a target variable for an explanatory variable, the model optimization method comprising:
generating expanded MR data by transforming training data; and
causing the prediction model to learn and optimizing the prediction model based on a first predicted value generated by the prediction model based on the training data, and a second predicted value generated by the prediction model based on the MR data.

14. A non-transitory computer readable recording medium storing a program for causing a computer to optimize a prediction model configured to generate predicted values of a target variable for an explanatory variable, the program causing the computer to execute:
generating expanded MR data by transforming training data; and
causing the prediction model to learn and optimizing the prediction model based on a first predicted value generated by the prediction model based on the training data, and a second predicted value generated by the prediction model based on the MR data.
